(19) United States
(12) Patent Application Publication
(10) Pub. No.: US 2017/0018423 A1
(43) Pub. Date: Jan. 19, 2017

(54) Apparatus and Method for Processing the Surface of a Workpiece Comprised of Sensitive Materials with an Ozone and Carbon Dioxide Treating Fluid

(71) Applicant: OEM Group, Inc., Gilbert, AZ (US)

(72) Inventors: Patrick Starrs, Newport (GB); Joshua A. Levinson, Zionsville, PA (US)

(21) Appl. No.: 15/209,756

(22) Filed: Jul. 14, 2016

Related U.S. Application Data
(60) Provisional application No. 62/193,055, filed on Jul. 15, 2015.

(51) Int. Cl. H01L 21/02; B08B 5/00; B08B 3/10; B08B 3/08; H01L 21/67; H01L 21/683

(52) U.S. Cl. CPC H01L 21/02076; H01L 21/67051; H01L 21/6835; B08B 3/10; B08B 3/08; B08B 5/00

(57) ABSTRACT

An process including supplying a mixture of a treatment liquid, ozone, carbon dioxide and optional agents for treatment of a non-diced or diced workpiece comprised of chemically sensitive materials within a system having a liquid supply line between a reservoir containing the treatment liquid and a treatment chamber housing the workpiece, one or more nozzles accepting the treatment liquid from the liquid supply line and spraying same onto the surface of the workpiece, including the process of spraying ozone introduced into an environment containing the workpiece, and the injection of carbon dioxide into the environment to preserve the workpiece support by controlling the liquid layer of the processing liquid, the processing temperature, and the introduction of carbon dioxide and ozone into the reaction chamber.

### CROSS-REFERENCE TO RELATED APPLICATIONS

This application claims the benefit of U.S. Provisional Application Ser. No. 62/193,055, filed on Jul. 15, 2015, by the present inventors, entitled “Apparatus and Method for Processing the Surface of a Workpiece Comprised of Sensitive Materials with an Ozone and Carbon Dioxide Treating Fluid,” which is hereby incorporated by reference in its entirety for all allowable purposes, including the incorporation and preservation of any and all rights to patentable subject matter of the inventor, such as features, elements, processes and process steps, and improvements that may supplement or relate to the subject matter described herein.

### STATEMENT REGARDING FEDERALLY SPONSORED RESEARCH OR DEVELOPMENT

Not Applicable.

### BACKGROUND OF THE INVENTION

This invention relates generally to an apparatus and process for treating a semiconductor substrate containing semiconductor features, and more specifically to the equipment and process for cleaning a substrate with ozone and carbon dioxide. Ozone diffusion cleaning techniques can be performed in various ways. These include spraying water onto the workpiece while injecting ozone into the water, spraying water on the workpiece while delivering ozone to the workpiece, delivering a combination of steam or water vapor and ozone to the workpiece, and applying water, ozone, light irradiation and sonic energy simultaneously to the workpiece. Spray techniques using water at elevated temperatures have been especially successful at increasing the removal rates of various organic films and contaminants from workpiece surfaces.

Certain metals that are commonly used on semiconductor wafers can corrode when exposed to ozone and heated water, but even metallic compounds used in semiconductors, comprised of metallic and non-metallic elements, may be damaged by processes intended to remove organic films and contaminants from workpiece surfaces. As the process temperatures increase, the chemical reaction rate of all reactions, including metal corrosion, also increases. Dissimilar metals in ohmic contact with each other can also create a galvanic cell potential or electrical interaction which may promote corrosion.

Several methods have been developed to reduce or avoid corrosion. These methods typically include reducing the process temperature and/or using additives that include various corrosion inhibitors. Reducing the temperature is generally undesirable because it slows down the reaction rates of the chemicals acting to remove the organic films or contaminants from the workpiece. Corrosion inhibitors, which generally include additives such as nitrates, silicates, and benzo triazole, have been relatively effective at reducing corrosion on predominantly aluminum films. The application of these inhibitors with the ozone cleaning techniques has allowed use of higher process temperatures, to achieve higher cleaning or strip rates, while substantially controlling corrosion of aluminum surfaces on the wafers.

Still, use of corrosion inhibitors in cleaning semiconductor wafers can be disadvantageous as it involves using an additional chemical or additive, the corrosion inhibitors must be appropriately mixed with the process liquid, and their effectiveness can vary with different metals and other process parameters. Accordingly, there is still a need for methods for efficiently cleaning a semiconductor wafers using the diffused ozone techniques, while also preventing corrosion of metals, such as copper and aluminum, on the wafers.

Treatment of diced workpieces presents a number of challenges. Diced wafers may typically be at the latter stage of wafer processing, so tend to be fully-featured with complete semiconductor devices, such as having all materials deposited and patterned, including the potentially sensitive semiconductor materials. The sensitive materials present potential corrosion issues with any processing, for example ozone or other chemical-based cleaning to remove unwanted or harmful materials. Diced wafers may be mounted onto tape films, which are attached to a frame to suspend both the tape and an attached wafer. Cleaning processes, such as that provided herein, must not degrade the tape or cause dice to otherwise become disconnected from a frame. The tape must not be degraded, caused to warp or become wavy, fall off of frame, or other undesired effect. For a diced workpiece to become disconnected from the tape may represent a loss of costly and valuable devices.

It would be a valuable addition to the art to provide a process that will permit diced wafer on tape on frame workpieces to be placed securely inside the chamber. Similarly, it would be a valuable addition to the art to provide a process that will not degrade the tape and adhesive used to suspend the diced wafer on a frame. Additionally, it would be a valuable addition to the art to provide a process that will not degrade the materials and features on the dice, not lose dice to any appreciable degree during the process application, while efficiently and effectively cleaning the targeted material.

### SUMMARY OF THE INVENTION

An apparatus for supplying a mixture of a treatment liquid, ozone, carbon dioxide and optional agents for treatment of a non-diced or diced workpiece comprised of chemically sensitive materials and a corresponding method are set forth. An embodiment of the apparatus comprises a liquid supply line used to provide fluid communication between a reservoir containing the treatment liquid and a treatment chamber housing the workpiece. A heater configured to heat the workpiece. Heating a workpiece by contact with treatment liquid supplied to the workpiece. One or more nozzles accepting the treatment liquid from the liquid supply line and spraying same onto the surface of the workpiece. Ozone simultaneously introduced into the environment containing the workpiece, with injection of carbon dioxide and optional agents into the environment.

A treatment solution, application technique, system, and method are described that extend the range of material compatibility for the processing or cleaning of workpieces or substrates comprised of chemically sensitive materials, including wafers used in the manufacture of devices for the semiconductor, optoelectronic, micro-electromechanical, and etc., industries. Workpieces may be processed at front-end-of-line (FEOL) or back-end-of-line (BEOL) and be either non-diced or diced. This apparatus and its associated methods are capable of replacing the expensive solvents, corrosive chemicals, and complex processes that are frequently applied to the processing or cleaning of chemically sensitive materials. As such solvents and corrosive chemicals are typically only compatible with a small range of materials, the present apparatus and method provide an extended range of compatibility.

An apparatus for supplying a mixture of a treatment liquid, ozone, carbon dioxide and optional agents for treatment of a non-diced or diced workpiece comprised of chemically sensitive materials, such as a non-diced or diced semiconductor workpiece, and a corresponding method are set forth. An exemplary embodiment of the apparatus comprises a liquid supply line that is used to provide fluid communication between a reservoir containing the treatment liquid and a treatment chamber housing the workpiece. A heater may be disposed to heat the workpiece, either directly or indirectly. The workpiece may be heated by heating the treatment liquid that is supplied to the workpiece. One or more nozzles accept the treatment liquid from the liquid supply line and spray it onto the surface of the workpiece. An ozone generator provides ozone simultaneously to the treatment liquid or separately into the environment containing the workpiece, with simultaneous injection of carbon dioxide and optional chemical agents into the treatment liquid or into this environment.

In an exemplary embodiment, workpieces are processed by applying a heated liquid and/or vapor chemical stream to its surface via spraying, immersion, bulk transfer, flow, etc. In general, a liquid layer may be formed whose thickness may be controlled through the use of one or more of the rotation rate, the flow rate of the treatment liquid, and/or the injection technique (e.g., nozzle design) used to the deliver the fluid stream to the workpiece surface. The constituents of the chemical stream—which in an exemplary embodiment includes deionized water, ozone, carbon dioxide, and optional chemical agents—contacts and/or diffuses to the workpiece surface and reacts with the target film (e.g., photoresist) or contaminant to be removed. Control of the liquid layer thickness may be required to permit ozone to more freely diffuse to the surface and to induce reasonable cleaning and stripping rates.

In this invention, the use of carbon dioxide has been discovered to be important in preventing corrosion of the sensitive materials that are to remain intact on the workpiece, as its interaction with the surface of these materials protects them from the chemical attack potentially induced by the other components of the chemical stream. In addition, the temperature of the process while delivering this chemical stream has also been discovered to be an important factor for preventing corrosion and for determining the removal rate of the target film or contaminant. Thus, it may be the addition of carbon dioxide and the use of an appropriate process temperature that permits application of the chemical stream containing ozone and other optional chemical agents for processing or cleaning workpieces with chemically sensitive materials.

In accordance with an embodiment of the apparatus and method, workpieces may be comprised of substrates that are non-diced or diced, with the process apparatus and method easily switching between both types through the use of appropriate holding assemblies (e.g., workpiece carriers or clamshells suspended inside a matching rotor). Non-diced workpieces may include intact wafers produced as part of FEOL and BEOL processing. Diced workpieces may include previously non-diced workpieces that have been segmented and attached to a suspending frame and support for BEOL processing. The dicing of workpieces for “die on frame” applications may have been accomplished using a variety of methods, including—but not limited to—mechanical, laser-based, or plasma-based techniques. Application of this invention enhances the processing or cleaning of diced workpieces without removing all or portions of the diced workpiece, and the apparatus and method described here may be conducive to treating the materials used for the frame (e.g., metals or plastic) and for suspending the diced workpiece (e.g., plastic tape with adhesive), which are typically comprised of sensitive materials.

In accordance with another embodiment of the apparatus and method, heated water vapor or steam can be used at ambient or elevated pressure instead of or in addition to liquid as a means of accelerating the stripping or cleaning rate. With steam, it may be possible to achieve workpiece temperatures above 100° C. Elevated pressures in the processing chamber also provide for use of higher ozone concentrations. Application of this embodiment would be subject to the corrosion limitations of the chemically sensitive materials incorporated into the workpiece and the simultaneous use of carbon dioxide in the chemical stream.

The present process provide for the manipulation of variables adapted or potentially adaptable to help overcome issues by, but not limited to, controlling the temperature of the heated water, the flow rate of liquid and the spray pattern delivered to workpieces inside the chamber, the application of carbon dioxide, the selection of the various potential chemical agents.

### BRIEF DESCRIPTION OF THE DRAWINGS

FIG. 1 is a schematic block diagram of an exemplary embodiment of an apparatus for treating a workpiece with a treatment fluid, ozone, and carbon dioxide with optional chemical agents added.

FIG. 2 is a schematic block diagram of an alternate exemplary embodiment of an apparatus for treating a workpiece in which the workpiece is indirectly heated and in which ozone and carbon dioxide are injected in a line containing a pressurized treatment liquid with optional chemical agents added.

FIG. 3 is a schematic diagram of an exemplary embodiment of a workpiece comprised of a non-diced substrate.

FIG. 4a is a schematic diagram of an exemplary embodiment of a workpiece comprised of a diced substrate held by a suspending frame and support.

FIG. 4b is a schematic side diagram of the exemplary embodiment of FIG. 4a cut at line A-A.

FIG. 5 is a schematic diagram of an exemplary embodiment of a multi-substrate carrier for multiple exemplary workpieces.

FIG. 6 is a schematic diagram of an exemplary embodiment of a single-substrate carrier for an exemplary workpiece.

FIG. 7 is a flow diagram of an exemplary process according to the present disclosure.

FIG. 8 is a schematic block diagram of an additional alternative embodiment of the system set forth in FIG. 1 wherein the ozone, carbon dioxide, treatment fluid, and optional chemical agents are provided to the workpiece along different flow paths.

FIG. 9 is a schematic block diagram of an embodiment of an apparatus for treating a workpiece in which pressurized steam, ozone, carbon dioxide, and optional chemical agents are provided in a pressurized chamber containing a workpiece.

FIG. 10 is a schematic block diagram of an additional alternative embodiment of an apparatus for treating a workpiece in which an ultra-violet lamp may be used to enhance the kinetic reactions at the surface of the workpiece.

### DESCRIPTION OF THE EXEMPLARY EMBODIMENT

A workpiece 10 may be a non-diced workpiece 30 or a diced workpiece 40. A workpiece 10 may be processed or cleaned via ozone diffusing through an aqueous layer or in an aqueous vapor/gas environment to oxidize, and thereby remove, either or both films and contaminants. Additives to the aqueous layer, e.g., the optional chemical agents, may enhance or enable the desired etching action of these films and contaminants, including, for example, but not limited to, photoresist, metals, and semiconductors. Optional chemical agents may include, but are not limited to, ammonium hydroxide, hydrochloric acid, and hydrofluoric acid. Injection of carbon dioxide into the treatment liquid or environment serves to protect the integrity of a sensitive substrate on the workpiece 10. Proper control of the process temperature, through heating of the treatment liquid, may also be important to achieving the desired etching action of the films and contaminants, and protection of a workpiece 10 substrate surface 12.

Workpieces 10 may be comprised of substrate materials of various types that may be processed with the apparatus and methods described here. Substrate surfaces 12 may include, but are not limited to, semiconductor, insulating, metallic, and organic films. Among these general types of materials are materials that are sensitive to ozone-based chemistry and the optional chemical agents. Such materials may be protected through the use of carbon dioxide and appropriate temperature control. Sensitive substrate materials may include both metals and semiconductor metal compounds. Some examples of sensitive substrate materials include, but are not limited to, silver (Ag), gallium arsenide (GaAs), lithium niobate (LiNbO3), aluminum (Al), gallium nitride (GaN), indium phosphide (InP), and indium tin oxide (“ITO”).

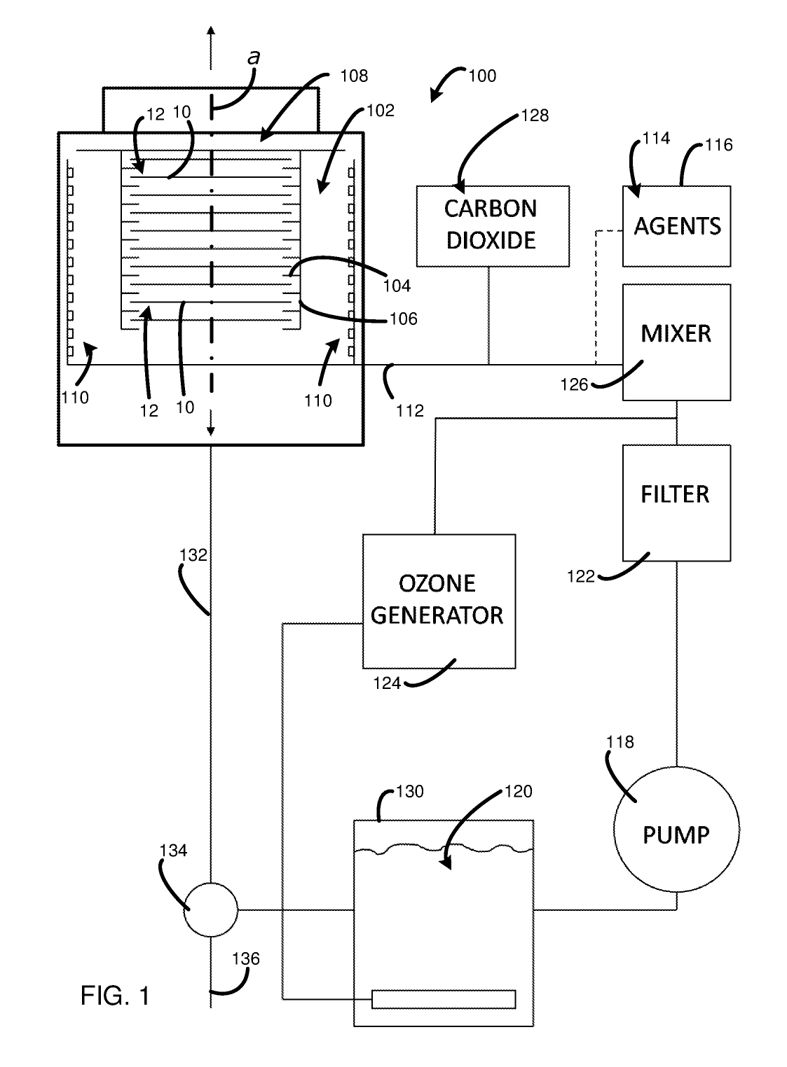

FIG. 1 diagrams an embodiment of a treatment system apparatus 100 suitable for providing a treatment liquid, ozone, optional chemical agents, and carbon dioxide for treatment of a workpiece 10 with substrate surface 12 comprising at least one chemically sensitive material. The treatment system 100 includes a treatment chamber 102 that contains one or more workpieces 10. The size of the chamber 102 may be as small as permitted by design considerations for any given workpiece capacity and may be cylindrical in shape. Although the system may be illustrated as a batch workpiece apparatus, it will be recognized that the system 102 may be readily adaptable for use in single workpiece 10 processing as well. The workpieces 10 are supported within the chamber by one or more supports 104. Supports may extend from a holder 106 mounted within a rotor assembly 108. The rotor assembly 108 may seal with the housing of the process chamber 102 to form a closed process environment. The rotor assembly 108 may spin so that the workpieces 10 may be spun about an axis a within the chamber 102 before, during, or after treatment.

One or more nozzles 110 are disposed within the treatment chamber 102 so as to direct a spray mixture of treatment liquid, ozone, optional chemical agents, and carbon dioxide onto the surface 12 of the workpieces 10. Nozzles 110 may direct a spray toward one or both sides of the workpieces 10. The liquid may also be applied in other ways besides spraying, such as flowing, bulk deposition, and immersion.

Treatment liquid 120, ozone, optional chemical agents 114, and carbon dioxide 128 are supplied to the nozzles 110 through a single fluid line 112. A variety of treatment agents 114 may be mixed into the fluid line 112. A reservoir 116 may store the agent 114 to be mixed, and the reservoir 116 may be in controlled fluid communication with a pump mechanism 118 that provides pressure along a fluid flow path within the fluid line 112 in order to supply treatment fluid 120 and agent 114 to the nozzles 110. An exemplary treatment fluid 120 may be deionized water, but other process fluids may be employed, such as other aqueous or non-aqueous solutions.

The flow path of the fluid line 112 may include a filter 122 to remove microscopic contaminants from the treatment liquid 120. Ozone may be generated by an ozone generator 124. Ozone may be injected into the fluid line 112. Optionally, the treatment liquid 120 and ozone are supplied to the input of a mixer 126, which may mix the ozone with the treatment liquid in an active or static fashion. Carbon dioxide 128 may be incorporated into the treatment liquid 120 within the fluid line 112. The treatment liquid 120, which may contain carbon dioxide 128, ozone, and an agent 114, may be provided to the nozzles 110. The nozzles 110 may spray the treatment liquid 120, which may contain carbon dioxide 128, ozone, and an agent 114, onto the surface 12 of the workpiece 10. Spraying the treatment liquid 120, which may contain carbon dioxide 128, ozone, and an agent 114, introduces ozone and carbon dioxide 128 into the environment of the treatment chamber 102.

The exemplary flow arrangement may be modified to permit ozone to be dispersed into the treatment liquid 120 within the treatment liquid reservoir 130. This can further concentrate ozone into the treatment liquid 120. Additionally, carbon dioxide 128 may be introduced to the treatment liquid 120 ahead of the mixer 126, to be actively or passively mixed into the fluid flow within the fluid line 112 with ozone.

In the exemplary embodiment of FIG. 1, spent treatment liquid 120 from the chamber 102 flows outward along a line 132 directed to a valve mechanism 134. This valve mechanism 134 may be operated to provide the spent liquid to either a drain output 136 or back to the treatment liquid reservoir 130. Repeated cycling of the treatment liquid 120 through the system 102 and back to the treatment liquid reservoir 130 can assist in elevating the concentration of ozone and carbon dioxide 128.

In the exemplary embodiment of FIG. 1, the ozone, agents 114, and carbon dioxide 128 may be injected into the treatment liquid 120 independently at selectable concentrations. The volume and concentration of ozone, agents 114, and carbon dioxide 128 introduced into the treatment liquid 120 may be completely independent of each other.

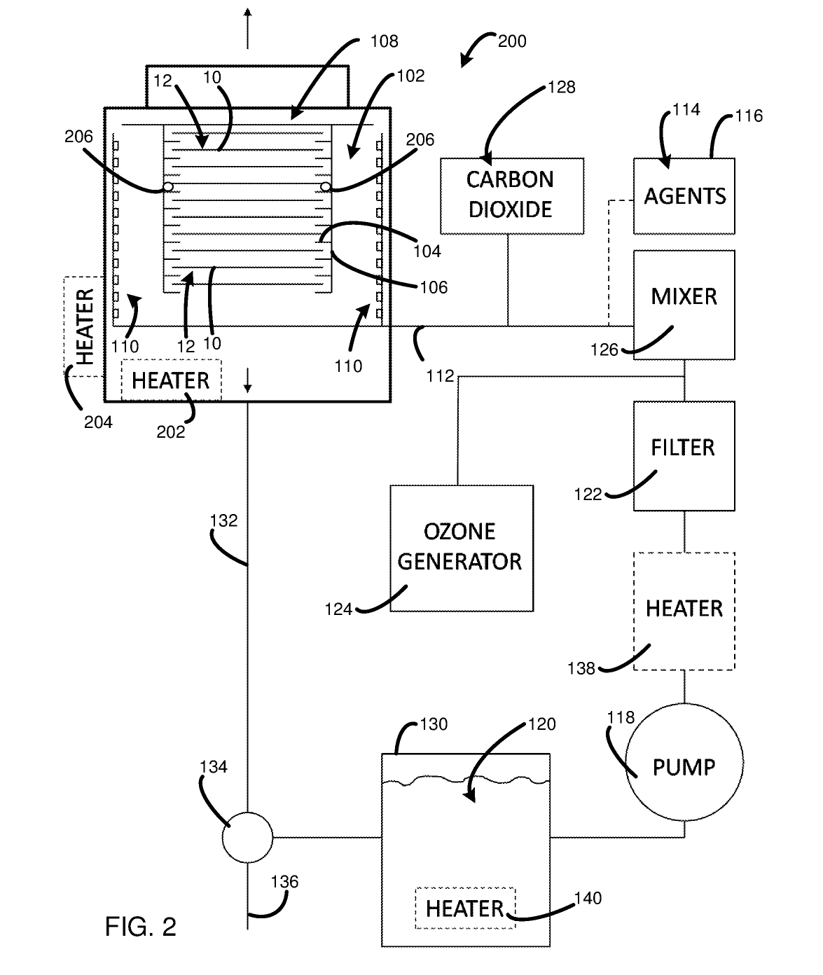

Referring now primarily to FIG. 2, another exemplary embodiment of a system 200 for delivering a fluid mixture for treating the surface 12 of a workpiece 10 is shown. It involves heating of the surfaces 12 of the workpieces 10 with a heated liquid that may be supplied along with a flow of ozone, optional chemical agents 114, and carbon dioxide 128. The system 200 may include one or more liquid heaters (138, 140, 202) used to heat the treatment liquid 120. The workpieces 10 can also be heated directly via conduction heaters 204. Another form of conduction heater 204 may include heating elements 206, portrayed in an exaggerated size in workpiece supports 104. Actual sizing may be appropriate to not interfere with the operation of the supports 104 and holders 106. A heating element 206 may merely be a heating element embedded in either or both the support 104 and holder 106. Either or both liquid heaters (138, 140, 202) and conduction heaters 204 may be used. Heaters (138, 140, 202) may include positions either or both inside and outside of the chamber 102. A heater 138 may be positioned within the fluid line 112, for example, after the pump 118. A heater 140 may be positioned inside the treatment liquid reservoir 130.

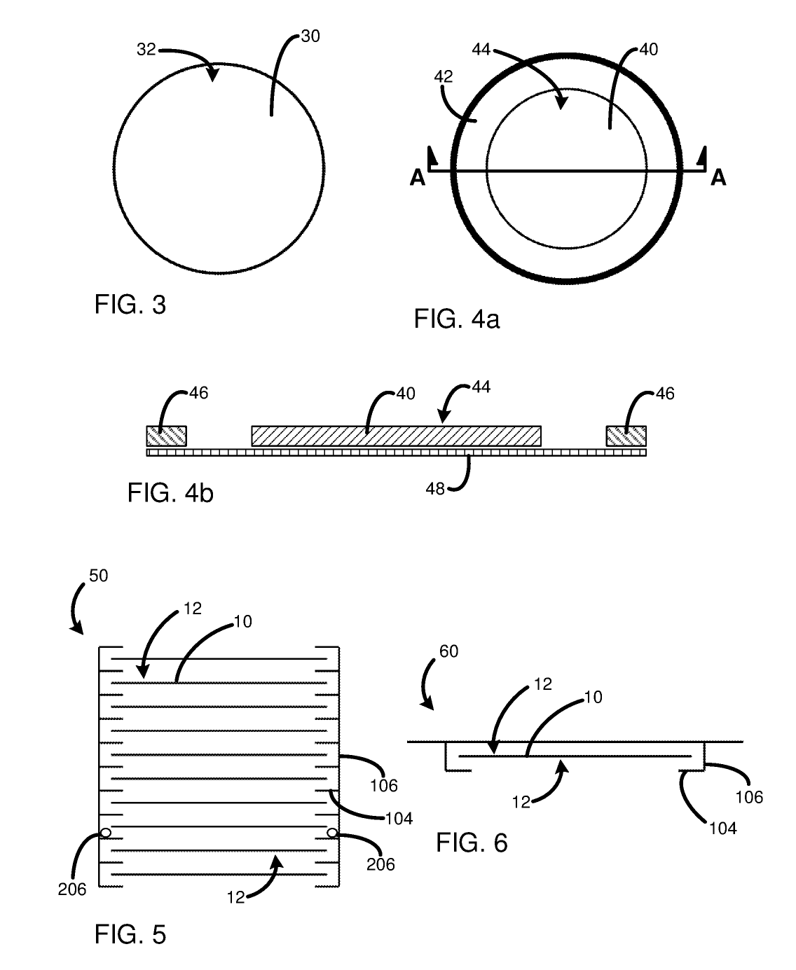

Referring now primarily to FIG. 3, an exemplary non-diced workpiece 30 is shown. Various sized non-diced workpieces 30, also referred to as wafers, are known in the field of semiconductors. The surfaces 32 of a non-diced workpiece 30 may be comprised of sensitive semiconductor materials upon which semiconductor features may be created.

Referring now primarily to FIG. 4a, an exemplary diced substrate 40 is shown. Various sizes of diced workpieces 40, typically cut apart from a non-diced workpiece 30, are known in the field of semiconductors. The exemplary frame and support 42 permits the holding of the diced workpiece 40. The frame and support 42 provides additional support and structure to the diced workpiece 40, so the diced workpiece 40 may be held securely in a processing chamber 102. The surfaces 44 of a diced workpiece 40 may be comprised of sensitive semiconductor materials upon which semiconductor features may be created. In the case of a diced workpiece 40, sensitive materials may be present in the frame and support 42 and may also be protected through the use of carbon dioxide 128 and appropriate temperature control.

Referring now primarily to FIG. 4b, a cut-through side view of the exemplary diced substrate 40 is shown. The exemplary embodiment may have a frame and support 42 that may comprise a frame 46 and a tape support 48. The frame 46 may be made of metals or plastics that might be sensitive to a typical cleaning process, treatment liquid 120 and processing materials, such as ozone, optional agents 114, and temperature. The current systems (100, 200, 800, 900, and 1000) and process 700 allows for control and adjustments that preserve the integrity and function of the frame 46. The tape support 48 may be made of a plastic polymer with adhesive that might be sensitive to typical cleaning processing, treatment liquid 120 and processing materials, such as ozone, optional agents, and temperature. Additionally, heat may cause ill-effects, such as warping and waviness, along with delamination of the tape from the frame and dice. As such, it the tape support 48 potentially be degraded by prior art processing. The current systems (100, 200, 800, 900, and 1000) and process 700 allows for control and adjustments that preserve the integrity and function of the tape support 48.

Referring now primarily to FIGS. 5 and 6, an exemplary multi-substrate carrier 50 and an exemplary single-substrate carrier 60 is shown. Carriers (50, 60) may also be referred to in the field of art as cassettes, clamshells, FOUPs, or holders, among other names.

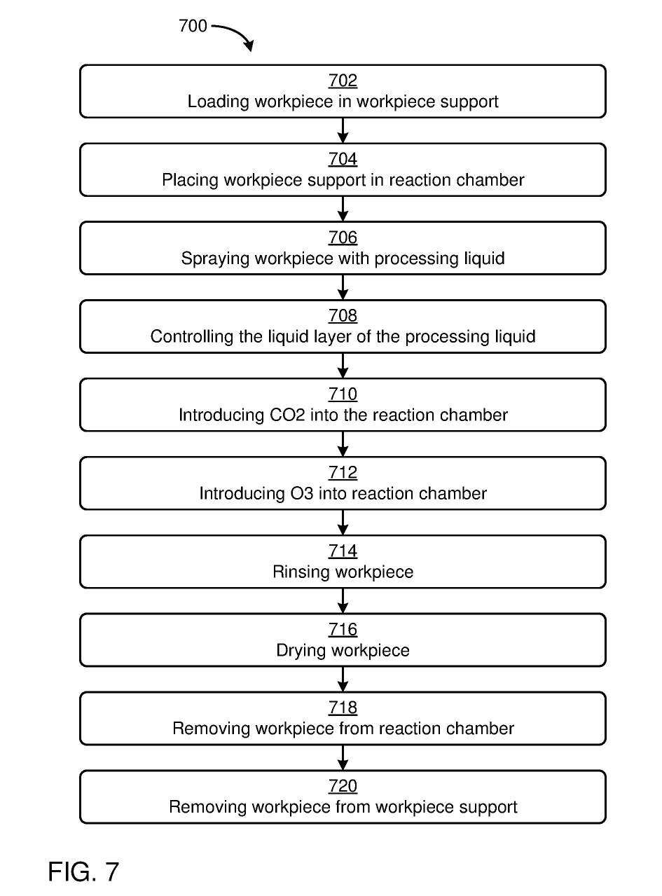

Referring now primarily to FIG. 7, an embodiment of the process 700 is shown. Process 700 may be performed in various systems, to include system 100 and system 200, shown in FIGS. 1 and 2. Process 700 may be used to strip or clean films or contaminants from a workpiece 10. The steps in the method of FIG. 7 are an example, and may be rearranged, shortened, or augmented for a specific application.

Process 700 may include loading 702 at least one workpiece 10 workpiece carrier (50, 60) that may be appropriate to the particular type of workpiece 10. An appropriate workpiece carrier (50, 60) may precisely corresponds to the support holder 106 positioned within the reaction chamber 102. Placing 704 the workpiece carrier (50, 60) may position the workpiece 10 in the reaction chamber 102. Alternatively, workpieces 10 may be placed into the chamber 102 in a carrierless manner, with an automated processing system (not shown). The reaction chamber 102 and its corresponding components may be constructed based on a spray tool platform, such as those available from OEM Group, of Gilbert, Ariz., USA.

Spraying 706 the workpiece 10 with a treatment liquid 120. Spraying 706 creates a thin liquid film on the workpiece surfaces 12. Heating the surface 12 of workpiece 10 may be accomplished by heating the treatment liquid 120.

Controlling 708 the liquid layer of the treatment liquid 120 may include rotating the workpiece 10. Controlling 708 the liquid layer may be accomplished by using one or more techniques. Additionally, a hydrophobic surface 12 may have a surfactant added to the treatment liquid 120 to assist in controlling 708 the liquid layer, where creating a thin liquid layer on the workpiece surfaces 12 may be desired. A surfactant may also be useful with a hydrophilic surface 12.

The workpiece 10 may be rotated about axis a by a rotor to thereby generate centripetal accelerations that thins the treatment liquid 120 layer. The flow rate of the treatment liquid 120 may also be used to control the thickness of the liquid layer. The treatment liquid 120 may be presented in a vapor form. Lowering the flow rate results in decreased liquid layer thickness. Nozzles 110 may also be designed to provide the treatment liquid 120 as micro-droplets thereby resulting in a thin liquid layer. Such delivery may reduce the reliance on rotation of the workpiece 10. Reducing the liquid layer thickness may permit the ozone to better to diffuse to the workpiece surface 12 where it may reacts to remove the contaminants.

Introducing 710 carbon dioxide 128 into the fluid line 112 during spraying 706, or otherwise into the reaction chamber 102 environment, may be done while maintaining temperature and liquid layer control. Introducing 710 carbon dioxide 128 permits the surface 12 of a workpiece 10 to become laden with carbon dioxide 128 prior to ozone exposure. The carbon dioxide 128 is seen to protect a chemically sensitive materials surface 12. If the water surface begins to dry, a brief spray of treatment liquid 120 may be activated to replenish the liquid film, keeping the workpiece 10 wet and at a desired elevated temperature.

Introducing ozone 712 may take place while injecting carbon dioxide 128. Agents may also be injected into the fluid flow path during its spraying 706, or otherwise into the reaction chamber 102 environment. System 100 may permit introducing ozone 712 to continue after the spraying 706 has stopped. If the treatment liquid 120 surface begins to dry, a brief spray may be activated to replenish the liquid film, keeping the workpiece 10 wet and at the desired elevated temperature. With continuous application of the treatment liquid, ozone, optional chemical agents, and carbon dioxide, the liquid layer thickness may be controlled using one of the methods described above. This, in turn, regulates the diffusion barrier for ozone to react with undesirable materials on the surface 12. Controlled spraying 706 may be helpful in controlling the reaction rate. For example, if using rotation, the liquid layer thickness effective for surface reaction may be achieved at high rotation speeds (e.g., >300 rpm, between 300 and 800 rpm, or even as high as or greater than 1500 rpm).

While ozone has a limited solubility in heated deionized water, the ozone may be able to diffuse through the liquid layer and react with the film or contaminant at the interface of the treatment liquid 120 and the surface 12. In the case of photoresist, the deionized water may assist in the reactions by hydrolyzing the carbon-carbon bonds of molecules in this organic layer. The higher temperature may speed up the chemical reaction cleaning, while the high concentration of ozone in the gas phase may promote diffusion of ozone through the liquid layer even though the liquid layer may not actually have a high concentration of dissolved ozone. The additional presence of dissolved carbon dioxide in the liquid layer and at the workpiece surface may protect chemically sensitive materials from ozone attack, disrupting the corrosion mechanism.

Elevated or higher temperatures mean temperatures above ambient or room temperature, for example temperatures above 20 or 25° C., and up to about 200° C. Typical temperatures ranging may include 25-150° C.; 25-70° C.; 55-120° C.; 75-115° C.; or 85-105° C. In the specific methods described, temperatures of 30-60° C. or 90-100° C. may be used, subject to the sensitivity of the materials contained in the workpieces. With temperatures above 100° C., liquid may be used in a pressurized chamber, or steam may be used. Use of lower temperatures (between 25-75° C., and more narrowly from 25-65° C.) may be useful where higher temperatures are undesirable. Still lower temperatures (e.g., 15-25° C.) may be used to avoid corrosion, as applicable.

After processing, rinsing 714 of the workpiece 10, and drying 716 of the workpiece may be performed. For example, a workpiece 10 may be sprayed with a flow of deionized water during rinsing 714. In drying 716, a workpiece 10 may then be subjected to one or more known drying techniques. Finally, removing 718 a workpiece 10 from a reaction chamber 102, and removing 720 a workpiece 10 from a workpiece carrier (50, 60) may be performed as appropriate for the particular equipment used.

To conserve water and achieve a very thin liquid layer, a “pulsed flow” of treatment liquid 120 or steam may be used. If this is insufficient to maintain the desired elevated surface temperature, embedded heaters (202, 204) may be used (e.g., on the chamber, on the support, etc.).

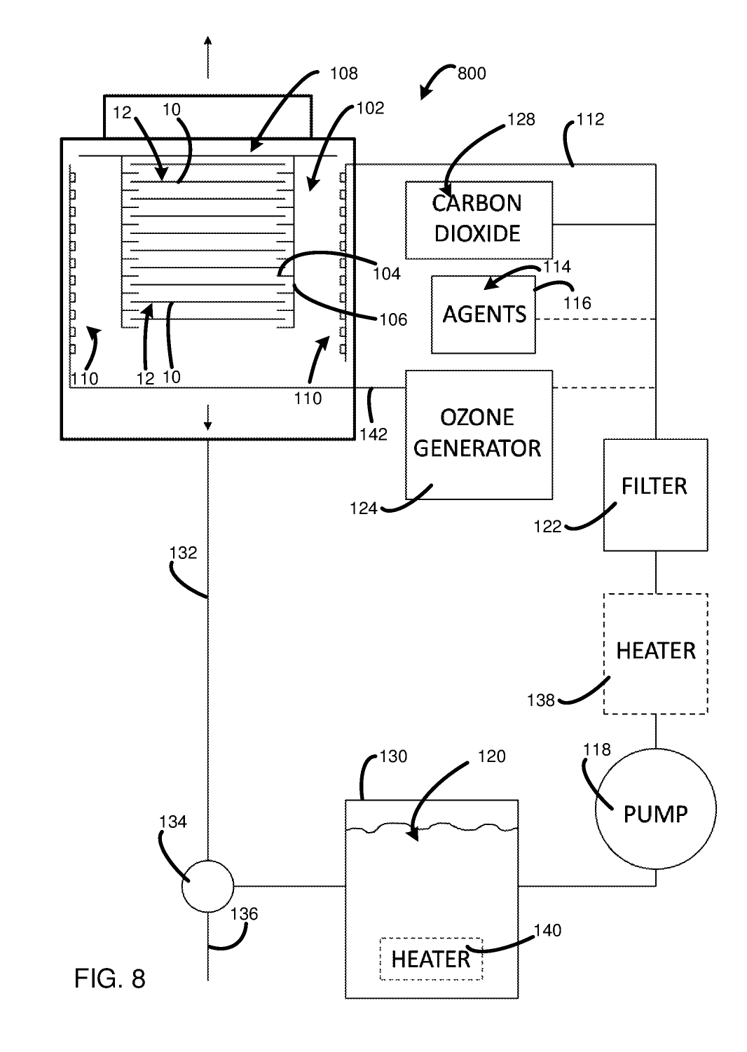

Referring now primarily to FIG. 8, the exemplary embodiment may be a system 800 having one or more nozzles 110 within the chamber 102 to provide ozone from an ozone generator 124 directly into the chamber 102. The heated treatment liquid 120 may be provided to the chamber 102 through a separate set of nozzles 110. The fluid line 112 may be separate from the ozone supply line 142. As such, injection of ozone into the fluid path for the heated treatment liquid 120 is optional. While not shown in FIG. 8, carbon dioxide 128 may also be provided to the chamber 102 through its own set of nozzles 110, separate from the heated treatment liquid 120, to be distributed to the workpiece surfaces 12 via the gas phase (as with the ozone).

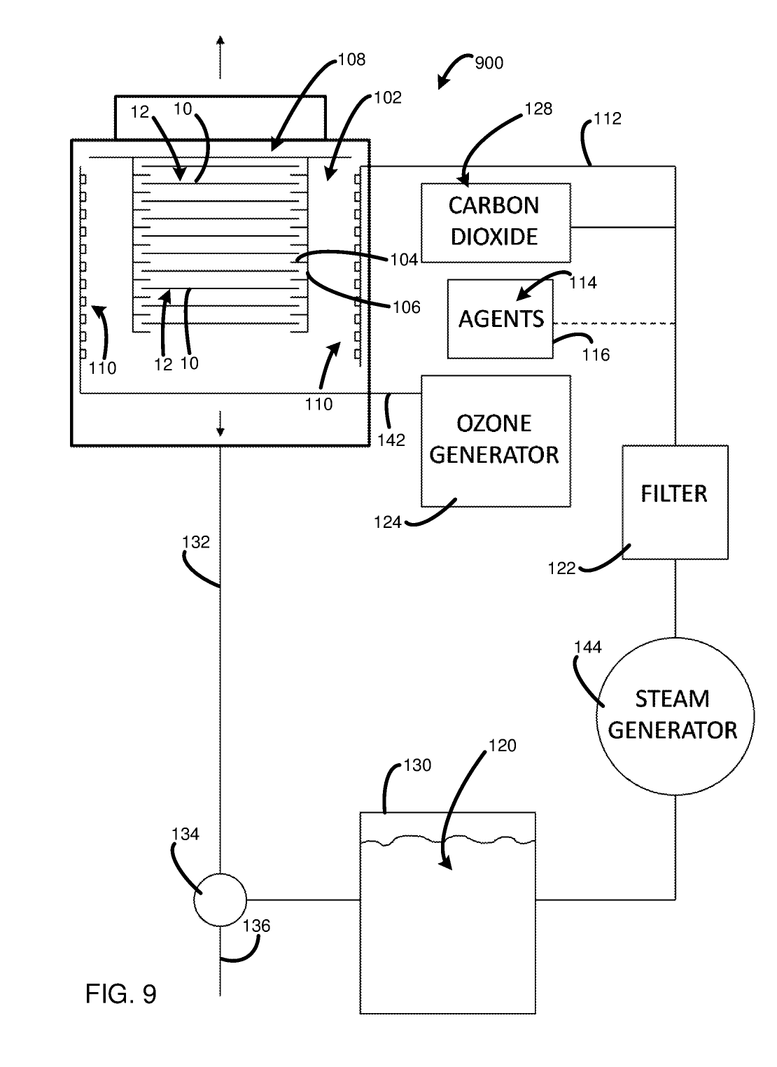

Referring now primarily to FIG. 9, the exemplary embodiment may be a system 900 having a steam boiler 144 that supplies steam under pressure to the process chamber 102. The chamber 102 may be sealed to thereby form a pressurized atmosphere. Steam or saturated steam at 100 or 110° C., up to about 150 or 200° C., typically about 110-130 or 140° C., may be generated by the steam boiler 144 and supplied to the chamber 102. Pressure in the chamber 102 generally ranges at 16, 18, or 20 up to about 90 psia, usually in the range of about 20-70; 25-50; and 30-45 psia, with 35 psia being typical during the wafer processing. Ozone may be directly injected into the chamber 102 as shown, and may be injected into the fluid line 112 for concurrent supply with the steam. With this system 900, workpiece surface 12 temperatures in excess of 100° C. can be achieved, thereby further accelerating the chemical reactions and reducing required process times. Use of such elevated temperatures may be subject to the sensitivity of the materials contained in the workpieces 10. The steam generator 144 in FIG. 9 may be replaced with a heater 138, as shown in FIGS. 2 and 8. While FIGS. 8 and 9 show the treatment liquid 120 and ozone delivered via separate nozzles 110, they may also be delivered from the same nozzles 110, using appropriate valves.

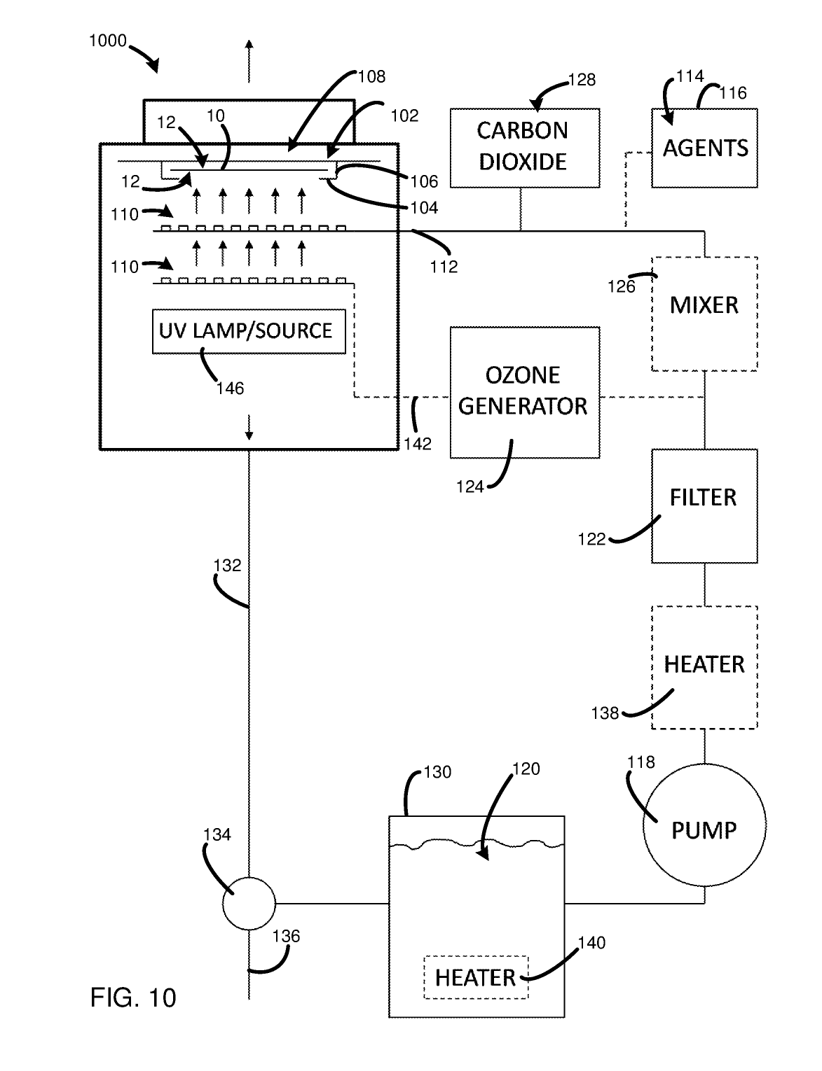

Referring now primarily to FIG. 10, the exemplary embodiment system 1000 may have a heating lamp 146, such as an ultra-violet or infrared lamp, which may be used to irradiate the surface 12 of the wafer during processing to enhance the reaction kinetics. Although this irradiation technique may be applicable to batch wafer processing, it may be more easily and economically implemented for single-wafer processing where the wafer may be more easily completely exposed to the UV radiation. Megasonic or ultrasonic nozzles may also be used. FIG. 10 shows an example of single-wafer processing.

As mentioned above, carbon dioxide 128 may be used in an ozone-based process as a means of protecting chemically sensitive materials on workpieces 10. As a consequence of this addition, the etch rate (or stripping or cleaning rate) of the targeted film or contaminant may be lower when compared to the same process run without carbon dioxide 128, due to its interaction with the surface materials and impact on the etch mechanism. Despite this reduction, its use permits the application of the ozone-based process to a wider range of substrates, affording the multiple advantages of this process compared to other more costly or less environmentally-friendly methods for film removal or cleaning.

Although the exemplary treatment liquid 120 for the disclosed application is deionized water, other treatment liquid 120 may also be used. In addition the optional chemical agents 114 listed above, other acidic or basic solutions may be used, depending on the particular surface 12 to be treated and the material that may be to be removed. Sulfuric acid may be useful in various applications, for example.

In the systems shown, ozone and carbon dioxide 128 gases may be separately sprayed, jetted, entrained in a treatment liquid 120 or gas, or otherwise introduced as a gas into the process chamber 102, where it can diffuse, impact, or displace through the treatment liquid 120 layer on the workpiece. The treatment liquid 120 may be heated and sprayed or otherwise applied to the workpiece 10, without ozone or carbon dioxide 128 injected into the treatment liquid 120 before the treatment liquid 120 may be applied to the workpiece 10. Alternatively, the ozone and carbon dioxide 128 may be injected into the treatment liquid 120, and then the ozone and carbon dioxide 128 containing treatment liquid 120 applied to the workpiece 10. If the treatment liquid 120 is heated, the heating may be better performed before the ozone is injected into the treatment liquid 120 to reduce the amount of breakdown in the treatment liquid 120 during heating. Typically, due to the larger amounts of ozone desired to be injected into the treatment liquid 120 and the low solubility of the ozone gas in the heated treatment liquid 120, the treatment liquid 120 will contain some dissolved ozone and may also contain ozone bubbles. It may be also possible to use both ozone gas injection directly into the process chamber 102 and to also introduce ozone into the treatment liquid 120 before the treatment liquid 120 is delivered into the process chamber 102. In all cases, the optional chemical agents 114 may be added to the treatment liquid 120.

Claim scope of the present disclosure may include an apparatus for cleaning a semiconductor workpiece having at least one sensitive semiconductor compound areas, comprising a reaction chamber, a semiconductor workpiece carrier suitable for insertion into the reaction chamber, a treatment liquid supply, a supply of supplemental treatment material that may include one or more of ozone, carbon dioxide, surfactant, and chemical cleaning agent, and a fluid line operatively connected to the treatment supply, the supply of supplemental treatment material, and a plurality of spray nozzles, and the plurality of spray nozzles positioned in the reaction chamber so as to direct the spray of processing material on the semiconductor workpiece. Additionally, the apparatus may further comprise the workpiece carrier comprising a workpiece support and a workpiece frame, and the workpiece support comprising an adhesive interface. Additionally, the apparatus may further comprise wherein the workpiece frame adherable to the workpiece support with the adhesive interface. Additionally, the apparatus may further comprise the semiconductor workpiece removably adherable to the workpiece support with the adhesive interface.

Alternatively, the claim scope of the present disclosure may include a method for cleaning a semiconductor workpiece having at least one sensitive semiconductor compound area, comprising the steps of placing a workpiece support holding the semiconductor workpiece in a reaction chamber, spraying the workpiece with a processing liquid, controlling the liquid layer of the processing liquid, introducing carbon dioxide into the reaction chamber, introducing ozone into the reaction chamber, rinsing the workpiece, removing the workpiece from the reaction chamber, and removing the workpiece from the workpiece support. Additionally, the method may further comprise attaching the semiconductor workpiece to a workpiece support, the semiconductor workpiece comprising a diced semiconductor component, adhering the semiconductor workpiece to the workpiece support, by an adhesive tape support interface on the workpiece support, and preserving the workpiece support by controlling the liquid layer of the processing liquid, the processing temperature, and the introduction of carbon dioxide and ozone into the reaction chamber so as to preserve at least one of the workpiece support tape support interface adhesion to the semiconductor workpiece. Alternatively, the method may further comprise preserving the tape support interface by controlling the liquid layer of the processing liquid, the processing temperature, and the introduction of at least one or more treatment supplementation materials into the reaction chamber from a group including ozone, carbon dioxide, and chemical agents, so as to preserve the tape support interface adhesion to the semiconductor workpiece.

The foregoing disclosure and description of the invention are illustrative and explanatory thereof. The examples contained in this specification are merely possible implementations of the current device and process, and alternatives to the particular features, elements and process steps, including scope and sequence of the steps may be changed without departing from the spirit of the invention. The present invention should only be limited by the following claims and their legal equivalents, since the provided exemplary embodiments are only examples of how the invention may be employed, and are not exhaustive.

I claim:

1. A method for cleaning a semiconductor workpiece having at least one sensitive semiconductor compound area, comprising the steps of:
placing a workpiece support holding the semiconductor workpiece in a reaction chamber;
spraying the workpiece with a processing liquid;
controlling the liquid layer of the processing liquid;
introducing carbon dioxide into the reaction chamber;
introducing ozone into the reaction chamber;
rinsing the workpiece;
removing the workpiece from the reaction chamber; and
removing the workpiece from the workpiece support.

2. The method of claim 1, further comprising:
attaching the semiconductor workpiece to a workpiece support, the semiconductor workpiece comprising a non-diced semiconductor component; and
preserving the sensitive semiconductor compound area by controlling the liquid layer of the processing liquid, the processing temperature, and the introduction of at least one or more treatment supplementation materials into the reaction chamber from a group including ozone, carbon dioxide, and chemical agents, so as to preserve the tape support interface adhesion to the semiconductor workpiece.

3. The method of claim 1, further comprising:
attaching the semiconductor workpiece to a workpiece support, the semiconductor workpiece comprising a diced semiconductor component.

4. The method of claim 3, attaching the semiconductor workpiece to a workpiece support further comprising:
adhering the semiconductor workpiece to the workpiece support with an adhesive tape support interface of the workpiece support.

5. The method of claim 4, attaching the semiconductor workpiece to a workpiece support further comprising:
preserving the tape support interface by controlling the liquid layer of the processing liquid and the introduction of carbon dioxide and ozone into the reaction chamber so as to preserve the tape support interface adhesion to the semiconductor workpiece.

6. The method of claim 1, further comprising:
attaching the semiconductor workpiece to a workpiece support, the semiconductor workpiece comprising a diced semiconductor component; and
adhering the semiconductor workpiece to the workpiece support with an adhesive tape support interface of the workpiece support.

7. The method of claim 6, further comprising:
preserving the tape support interface by controlling the liquid layer of the processing liquid and the introduction of carbon dioxide and ozone into the reaction chamber so as to preserve the tape support interface adhesion to the semiconductor workpiece.

8. The method of claim 1, further comprising:
attaching the semiconductor workpiece to a workpiece support, the semiconductor workpiece comprising a diced semiconductor component;
adhering the semiconductor workpiece to the workpiece support with an adhesive tape support interface of the workpiece support; and
preserving the tape support interface by controlling the liquid layer of the processing liquid and the introduction of carbon dioxide and ozone into the reaction chamber so as to preserve the tape support interface adhesion to the semiconductor workpiece.

9. The method of claim 1, further comprising:
attaching the semiconductor workpiece to a workpiece support, the semiconductor workpiece comprising a diced semiconductor component;
adhering the semiconductor workpiece to the workpiece support, by an adhesive tape support interface on the workpiece support; and
preserving the workpiece support by controlling the liquid layer of the processing liquid, the processing temperature, and the introduction of carbon dioxide and ozone into the reaction chamber so as to preserve at least one of the workpiece support tape support interface adhesion to the semiconductor workpiece.

10. The method of claim 1, further comprising:
attaching the semiconductor workpiece to a workpiece support, the semiconductor workpiece comprising a diced semiconductor component;
adhering the semiconductor workpiece to the workpiece support with an adhesive tape support interface of the workpiece support; and
preserving the tape support interface by controlling the liquid layer of the processing liquid, the processing temperature, and the introduction of at least one or more treatment supplementation materials into the reaction chamber from a group including ozone, carbon dioxide, and chemical agents, so as to preserve the tape support interface adhesion to the semiconductor workpiece.

11. An apparatus for cleaning a semiconductor workpiece having at least one sensitive semiconductor compound areas, comprising:
a reaction chamber, a semiconductor workpiece carrier suitable for insertion into the reaction chamber, a treatment liquid supply, a supply of supplemental treatment material that may include one or more of ozone, carbon dioxide, surfactant, and chemical cleaning agent, and a fluid line operatively connected to the treatment supply, the supply of supplemental treatment material, and a plurality of spray nozzles; and
the plurality of spray nozzles positioned in the reaction chamber so as to direct the spray of processing material on the semiconductor workpiece.

12. The apparatus of claim 11, further comprising:
the workpiece carrier comprising a workpiece support and a workpiece frame; and the workpiece support comprising an adhesive interface.

13. The apparatus of claim 12, wherein:
the workpiece frame adherable to the workpiece support with the adhesive interface.

14. The apparatus of claim 13, wherein:
the semiconductor workpiece removably adherable to the workpiece support with the adhesive interface.
